(19) United States
(12) Patent Application Publication
(10) Pub. No.: US 2018/0061731 A1
(43) Pub. Date: Mar. 1, 2018

(54) ELECTRONIC CHIP DEVICE WITH IMPROVED THERMAL RESISTANCE AND ASSOCIATED MANUFACTURING PROCESS

(71) Applicant: 3D PLUS, BUC Cedex (FR)

(72) Inventor: Christian VAL, SAINT REMY-LES-CHEVREUSE (FR)

(21) Appl. No.: 15/560,479

(22) PCT Filed: Mar. 22, 2016
(86) PCT No.: PCT/EP2016/056204

§ 371 Date: Sep. 21, 2017

(30) Foreign Application Priority Data
Mar. 24, 2015 (FR) 1552457

(51) Int. Cl. H01L 23/367; H01L 23/433; H01L 23/00

(52) U.S. Cl. CPC H01L 23/367; H01L 23/4334; H01L 24/48; H01L 2224/45144; H01L 24/85; H01L 2224/4824; H01L 2224/85205; H01L 24/45

(57) ABSTRACT

An electronic chip device with improved thermal resistance comprises at least one electrical connection pad with an electrical interconnection link, at least one thermal pad arranged on a face of the chip, at least one heat exchange element, and at least one thermal link between a thermal pad and a heat exchange element.

The present invention relates to an electronic chip device and an associated manufacturing method. An electronic chip device is understood to mean the electronic chip itself and additional elements.

It is known to use a radiator or heat exchanger with very high thermal conductivity to evacuate the heat released by an electronic chip or a stack of electronic chips.

Such heat exchangers made of copper have a thermal conductivity of the order of 350 W/m/° C., made of diamond (or “like carbon”) a thermal conductivity of the order of 1500 to 1800 W/m/° C., and made of carbon nanotubes a thermal conductivity of the order of 1500 to 1800 W/m/° C.

Such radiators or heat exchangers do not make it possible to transmit heat in proportion to their respective thermal conductivity because the overriding parameter remains the thermal resistance of the chip/radiator interface, whether these radiators be bonded or soldered.

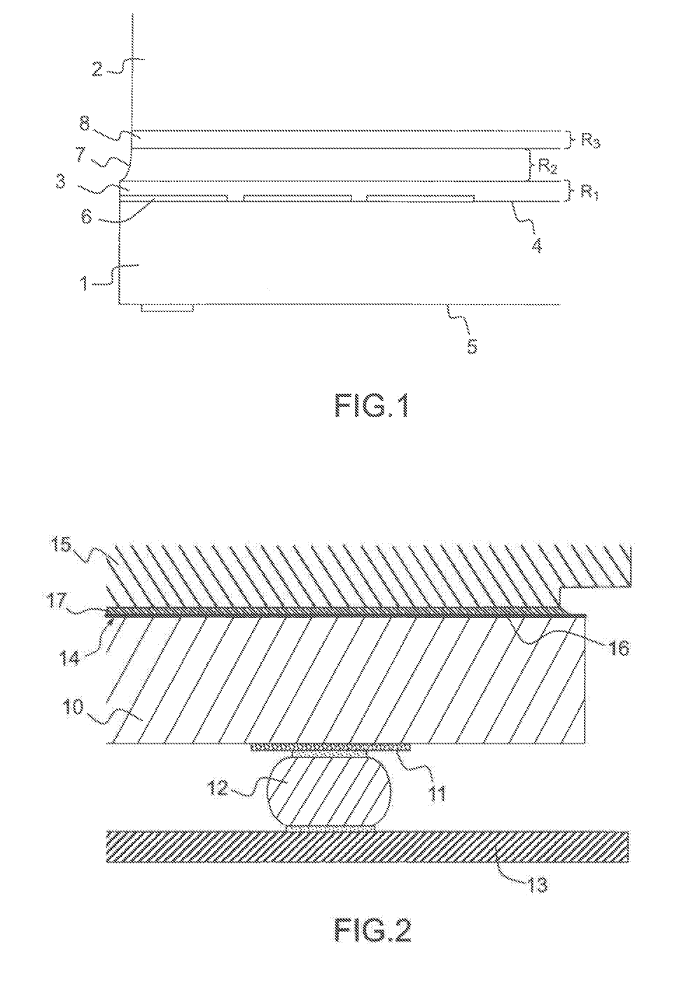

As illustrated in FIG. 1, the thermal resistivities (opposites of the thermal conductivities) of each constituent of the thermal chain of an electronic chip device, from the electronic chip 1 to the heat exchange element 2, add together as follows:

the interface 3, of resistivity R1, between the material linking the radiator and the rear face 4 of the chip (face opposite the active face 5). The interface is generally formed by a metal deposition on the rear face of the chip 1 in order to avoid the thermal insulating effect of the native silica 6 that more or less covers this silicon face and is of high resistivity. These materials may be alloys of tungsten W and of titanium Ti, or alloys of nickel Ni, of chromium Cr and of gold Au etc.;

the resistivity R2 of the material 7 that ensures the mechanical link to the heat exchange element 2, which material may be, for example, a thermal adhesive (whose thermal conductivity varies from about 5 W/m/° C. to 20 W/m/° C.) or a solder more or less rich in lead (whose thermal conductivity varies from 35 to 50 W/m/° C.); and

the resistivity R3 of the material 8 deposited on the heat exchange element 2 to ensure its link, which material may for example be a metal deposition performed under vacuum.

Several major computer manufacturers have tried to circumvent the difficulty associated with the thermal resistance of the interface by using techniques that are relatively efficient but very complicated to implement, such as IBM with its IBM 3081 computer, which avoided the resistances or resistivities R1+R2+R3 of the materials by directly contacting the two surfaces (rear face of the chip and heat exchange element or radiator). The surfaces were polished so as to result in a pseudo-bonding of the two parts and consequently to virtually eliminate the interfacial resistance. This very cumbersome and costly system has since been abandoned (cf R C Chu, U. P. Hwang and R. E. Simons, “Conduction Cooling for an LSI Package: A one dimensional Approach”, IBM J. Res. Div., Vol 26, P45-54, 1982).

Hitachi, with its FACOM M-780 computer, bypassed the difficulty by injecting coolant under pressure directly onto the rear face of the chip (cf H. Yamamoto, T. Udagawa and M. Suzuki, Cooling System for FACOM M-780, “Large Scale Computer in Cooling Technology for Electronic Equipment”, W. Aung, Ed, Hemisphere Publishing, p 701-714, 1984).

AT&T, with its WE 32100 MICROPAC computer, used a silicon substrate in place of the PCB, so the heat passes through the silicon of the chip to the ground plane, which is linked to the radiator by an organic material (adhesive) that therefore has low thermal conductivity (around 5 to 10° C./W) (cf C. J. Bartlett, J. M. Segelken and N. A Teneketges, “Multichip Packaging Design for VLSI-based Systems”, IEEE Trans. Compon. Hybrids Manuf. Technol., Vol. CHMT-12 (No. 4) p 647-653, 1987).

FIG. 2 shows a cross-section of an inverted chip device 10, or “flip chip”, borne on a substrate. The electronic chip 10 comprises pads 11 that are generally distributed over all or part of its active surface, on which pads balls of solder 12 have been deposited. The electrical interconnection of the chip with balls to the substrate 13 is achieved by reflow. The rear face 14 of the chip 10 or the non-active face may be linked to a heat exchange element 15 or radiator, in order to dissipate the heat generated by the chip 10 during its operation.

A portion of the heat is directed toward the electrical interconnection balls 12 depending on the thermal resistance of the substrate 13 (generally a PCB with low thermal conductivity). The pads 11 onto which the balls 12 are soldered generally have a complicated metallurgy of the aluminum/titanium/tungsten/nickel/gold type, the total thickness being about 1 μm. When the balls 12 are reflowed, intermetallic alloys are formed between the gold, the nickel and the lead-based solder; these alloys generally have fairly low thermal conductivity (20 to 50 W/m/° C.).

Another portion of the heat will be directed toward the rear face 14 of the chip 10, which is why the heat exchange element 15 is generally positioned on this rear face 14.

The heat passes through the silicon forming the chip 10 and whose thermal conduction is 140 W/m/° C., this being much higher than that of the balls 12 but much lower than that of the heat exchange element 15, generally made of copper (390 W/m/° C.).

The heat flux then passes through the interface 16 formed of a metal deposit (about 1 μm) and then the solder 17 itself, whose thermal conductivity is of the order of 40 W/m/° C.

The heat flux then enters the heat exchange element 15 in order to be dissipated therefrom.

When the chip is designed, the current node zones (hot spots) are known and localized in order preferentially to add thermal pads at these locations on the photolithography mask, which is necessary in any case for the electrical pads.

The use of ultrasonic “ball bonding” wiring makes it possible to weld a wire onto a pad, generally made of aluminum, of the chips. The friction induced by the displacement of the ultrasonic welding tool, which, at ultrasonic frequency, is of the order of 0.1 μm, makes it possible to raise the temperature of the interface to a temperature of 500° C. to 600° C. This high temperature with regard to the melting temperatures of the aluminum generally forming the pads (660° C.) and of the gold (1064° C.) generally forming the wire allows a self-diffusion of the aluminum atoms of the pad and of the gold atoms of the wire; in other words, it forms a perfect metallurgical link, also called a “solid solution”, without any interface since there is “interpenetration” of the respective atoms of gold and of aluminum, of the order of a few μm.

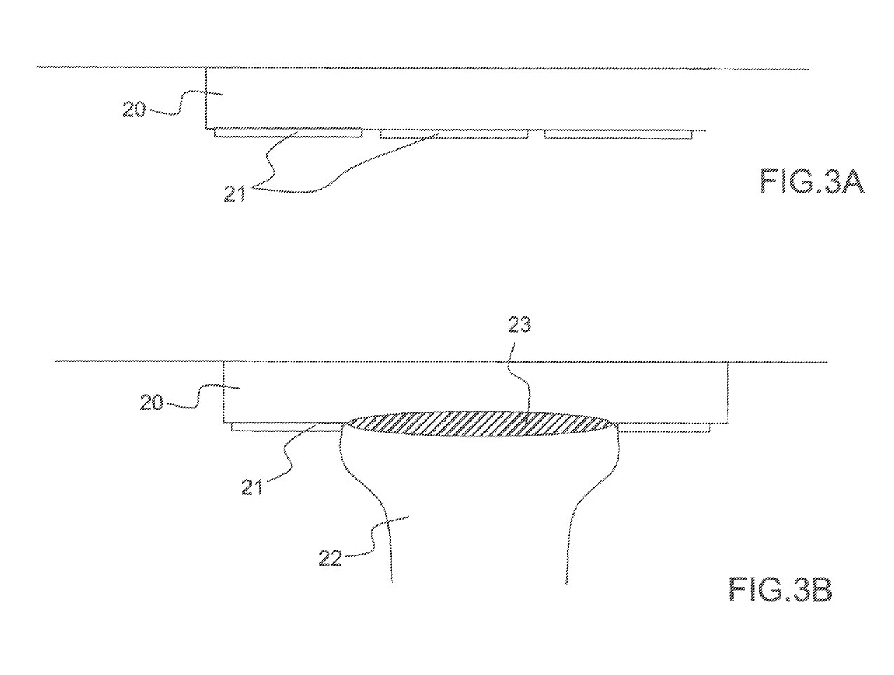

FIG. 3A shows a pad 20 made of aluminum or an aluminum alloy covered with a more or less continuous native layer 21 of aluminum oxide Al₂O₃.

FIG. 3B shows the same pad surface after ultrasonic welding of the ball 22 of the wire (for example made of gold), where the aluminum oxide has been destroyed by virtue of the ultrasound, and the link between the gold ball and the aluminum pad is the result of a self-diffusion or interdiffusion 23 of the atoms of gold and of aluminum during the welding; in other words, there is a metallurgical link without an interface.

Therefore, with reference to the flip chip of FIG. 2, it is observed that the interface between the ball 12 and the pad 11 of the chip 10 is eliminated; moreover, the thermal conductivity of the ball 12, which is of the order of 30 to 40 W/m/° C., is replaced by that of the wires made of gold (317 W/m/° C.) or silver (429 W/m/° C.), i.e. around ten times greater. On the other hand, the portion of the heat flux flowing through the rear face 14 must pass through the silicon (140 W/m/° C.) and the interfaces 16 and 17 before reaching the heat exchange element 15.

One aim of the invention is to mitigate these problems.

According to one aspect of the invention, there is provided a stack of at least one electronic chip device with improved thermal resistance comprising at least one electrical connection pad with an electrical interconnection link, at least one thermal pad arranged on a face of the chip, at least one heat exchange element, and at least one thermal link between a thermal pad and a heat exchange element, wherein a portion of a heat exchange element, said portion being situated facing an electrical connection pad, with an electrical interconnection link, of an electronic chip comprises an aperture preventing contact with said electrical interconnection link.

Such a stack of chips densifies the electronic function, but this leads to an increase in the power density per unit of volume and thus limits the number of chips able to be stacked.

Thus, the evacuation of the heat released by the activity of the electronic chip is improved, while avoiding the presence of an interface between the chip and the heat exchange element or radiator.

We find ourselves back in the position of mainframe computer manufacturers who, in the 1980s, sought to reduce the thermal resistance of the interface with the chip by using very unwieldy means that did not completely eliminate this thermal resistance.

According to one embodiment, said heat exchange element comprises tabs arranged facing the corners of the corresponding chip.

In one embodiment, the electronic chip (31, 51, 72) device(s) (30, 50) comprise a portion of said heat exchange element (36, 59), said portion being arranged facing a thermal pad (34, 61), comprising an aperture.

It is thus easy to produce the thermal links between a chip and the heat exchange element.

According to one embodiment, the thermal link(s) of the electronic chip device(s) comprise at least one thermally conductive wire.

The use of thermally conductive wires as a thermal link is now easy to implement and less expensive.

According to one embodiment, the face of a chip comprising at least one thermal pad is the active face or front face of the chip.

Thus, there is conduction of the heat, directly from the hot spots of the active (front) face of a chip, without passing through the passive (rear) face of the chip.

Furthermore, a single mask-transfer step on the active face of the chip makes it possible to produce the electrical connection pads and the thermal connection pads.

For example, a portion of a heat exchange element, said portion being situated facing an electrical connection pad, with an electrical interconnection link, of an electronic chip is raised in such a way as to avoid contact with said electrical interconnection link.

Thus, the evacuation of the heat is improved without creating problems on the electrical link of the electrical pads.

As a variant, the front face of a chip comprising at least one thermal pad is the passive face or rear face of the chip.

This is particularly useful when the active face of the chip has too many electrical pads with respect to its surface area or when the high working frequencies of the chip would be disturbed by thermal pads that could electronically couple with certain signals.

For example, the electronic chip device(s) comprise a substrate in which a portion situated facing electrical connection pads, with an electrical interconnection link, of the active face is provided with an aperture in such a way as to avoid contact with said electrical interconnection link.

Thus, when chips, with the active face at the bottom, are wired directly onto the substrate by virtue of an aperture in the latter, as it is not possible to position thermal pads on this active face, they may then be positioned on the non-active (passive) face and be connected to the heat exchange element by virtue of thermal wires.

According to one aspect of the invention, there is also provided a method for manufacturing an electronic chip device or a stack of electronic chip devices, comprising a mask-transfer step on the active face of the chip or chips, using a mask comprising at least one aperture intended for an electrical connection pad, and at least one aperture intended for a thermal pad.

The invention will be better understood upon studying some embodiments described by way of entirely non-limiting example and illustrated by the appended drawings, in which:

FIGS. 1 and 2 schematically illustrate electronic chips according to the known prior art;

FIGS. 3a and 3b schematically illustrate wiring according to the known prior art;

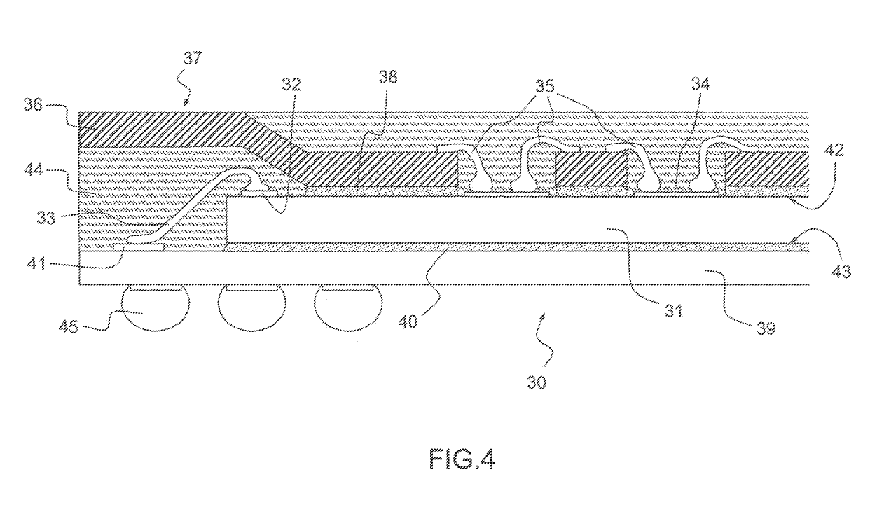

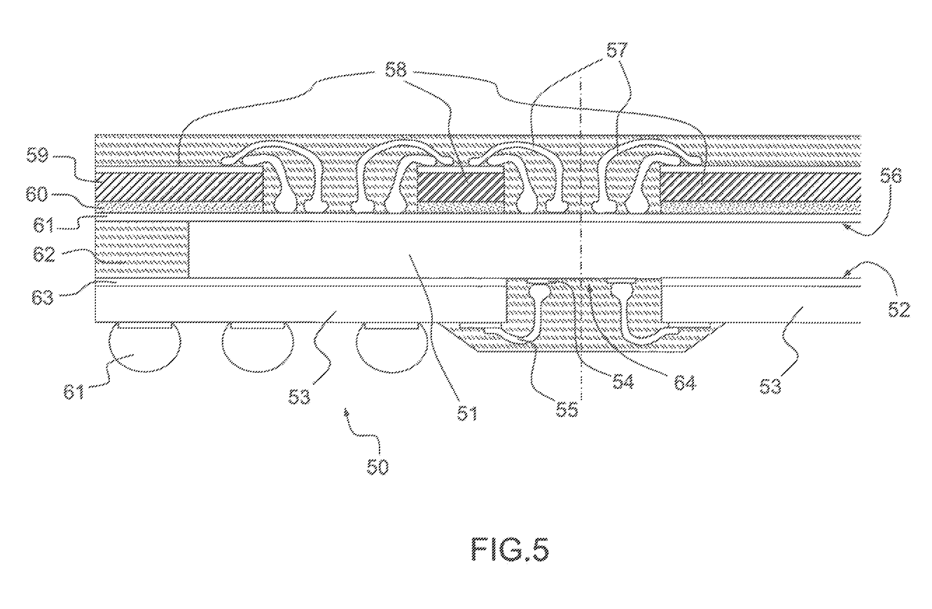

FIGS. 4 and 5 illustrate a (2D) chip device according to one aspect of the invention; and

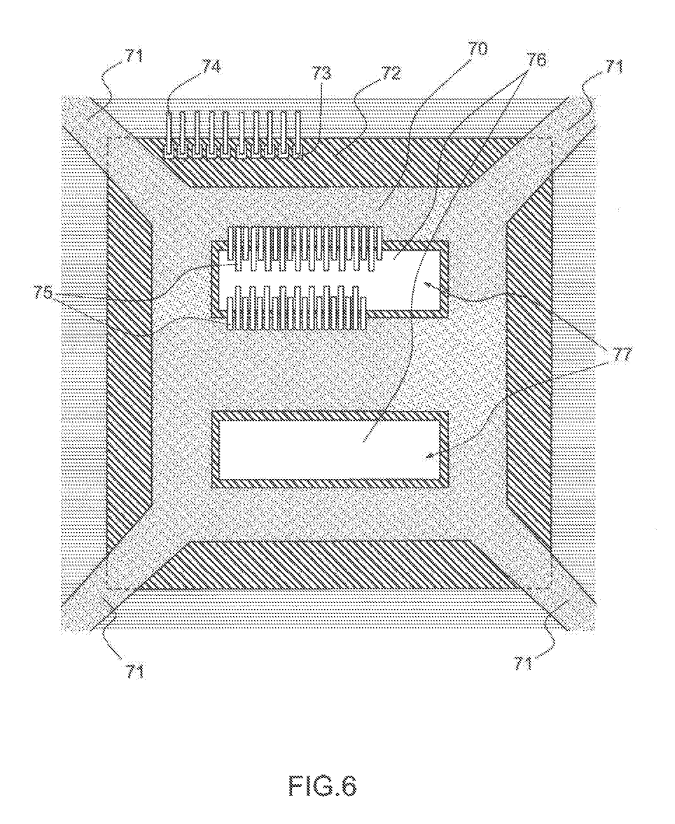

FIG. 6 illustrates a stack of electronic chip devices according to one aspect of the invention.

In all of the figures, elements having identical references are similar. The embodiments described are entirely non-limiting.

In the present description, features and functions well known to those skilled in the art are not described in detail.

FIG. 4 shows a 2D electronic chip 31 device 30, in the form of a package and an electrical connection pad 32 with electrical interconnection links, such as an electrical wire 33.

Thermal pads 34 are linked by thermal links 35 to a heat exchange element 36.

In the example shown, which is particularly beneficial, a portion 37 of the heat exchange element 36, said portion being situated above electrical connection pads 32, with electrical interconnection links 33, of the electronic chip 31 is raised in such a way as to avoid contact with said electrical interconnection links 33.

The heat exchange element 36 or radiator may be bonded with a flexible adhesive of the elastomer type, this being very important since new technologies involving low-dielectric-constant chips, termed “Cu/low-k devices”, have a very low tolerance to mechanical stresses. The flexible adhesive may be silicone-based and therefore highly deformable; these adhesives are very poor conductors of heat (less than 1 W/m/° C.) and lead to very high thermal resistances (of the order of a few ° C./W to a few tens of ° C./W). This is completely avoided by virtue of wiring the thermal linking wires 35 onto the heat exchange element 36, which ensures complete mechanical decoupling.

The chip 31 is bonded to the substrate 39 by an adhesive 40. Pads 41 of the substrate may electrically link the substrate 39 to electrical pads 32 of the chip 31 using the electrical wires 33, while not mechanically stressing the chip.

The heat exchange element 36 comprises raised portions in order to avoid touching the electrical linking wires 33.

The heat exchange element 36 could protrude from the package on one or 4 sides so as to form fins that would enable even better cooling in the case of convection cooling. In FIG. 4, the heat exchange element 36 is flush with one or more sides of the package, and is then able to be linked to a cold source.

In the embodiments described, when the chip is designed, the current node zones (hot spots) are grouped together so as preferentially to add thermal pads at these locations on the photolithography mask that is also necessary for the electrical pads.

In FIG. 4, the active face or front face 42 is at the top and the passive face or rear face 43 is at the bottom. The chip 31 is set in resin 44.

The substrate 39 is provided with balls 45 ready to be transferred onto a substrate, for example a printed circuit board.

FIG. 5 shows a variant for a 2D chip 51 device 50 in package form. Many chip 51 devices 50 used as memories are wired, as in FIG. 5, with the active face 52 downward, directly wired onto the substrate 53 by means of electrical connection pads 54 and of electrical wires 55 passing through an aperture 64 in the substrate 53. It is therefore possible to use the passive face 56 of the chip 51 to transfer heat via the thermal wires 57 and the heat exchange element 58.

The benefit of this approach is the use of a heat exchange element 59 that must be mechanically decoupled in order not to stress the chip 51; the flexible adhesive 60 used, generally of the elastomer family, is a very poor conductor of heat (less than 1 W/m/° C.).

The flexible adhesive 60 is arranged on a deposition 61, generally of gold and of nickel, considered as a large thermal pad on the electronic chip 51. The electronic chip 51 is set in resin 62 and is bonded to the substrate 53 by adhesive 63.

The substrate 53 is provided with balls 61 ready to be transferred onto a substrate, for example a printed circuit board.

FIG. 6 shows a 3D application making it possible to produce a stack of at least one electronic chip device when the electronic chip devices or levels are stacked. FIG. 6 shows a plan view of a device of the stack.

The radiator or heat exchange element 70 transfers the heat, for example by virtue of four straps or tabs 71 situated in the four corners of the heat exchange element 70, arranged above the four corners of the electronic chip 72.

Other arrangements of the straps or tabs 71 may, as a variant, be used depending on the position of the electrical pads 73 and electrical wires 74 for the electrical linking of the electronic chip 72.

In FIG. 6, the electrical pads 73 and the electrical wires 74 being situated on edges of the electronic chip 72, the radiator or heat exchange element 70 may or may not be raised in such a way as to avoid contact with the electrical wires 74. In any case, there can be no electrical wires 74 under the radiator 70 or under the straps 71 because, after stacking, the sawing of the module would cause the cross sections of the electrical wires 74 to match the cross sections of the straps 71 of the radiator 70, which would create a short circuit.

In the particularly beneficial embodiment of FIG. 6, the heat exchange element 70 comprises an appropriate cut-out so as to avoid any contact with the electrical wires 74.

Thermal linking wires 75 are wired onto thermal pads 76 arranged on the active face of the electronic chip 72.

The thermal wires 75 are connected to the heat exchange element 70 by wiring through apertures 77 produced in the heat exchange element 70, facing the thermal pads 76.

The invention also relates to a method for manufacturing an electronic chip device 30, 50 or a stack (3D chip) of electronic chip devices 30, 50, comprising a mask-transfer step on the active face of the chip or chips, using a mask comprising at least one aperture intended for an electrical connection pad, and at least one aperture intended for a thermal pad.

Thus, the present invention makes it possible to improve the transfer of heat from the hot spots of the very thin active surface of the chip (less than 1 μm) to the point said heat is evacuated, without passing through the thermal resistances of the interfaces.

Furthermore, the invention does not require any additional chip processing steps.

The invention implements a thermal interconnection directly at the source of the heat emission, and not after the heat has passed through the chip to reach the passive face.

The invention implements a ball bonding method that is very widely used in the interconnection of chips, including latest-generation chips. Indeed, since the latter are formed of dielectrics that are very sensitive to stresses and termed “Cu/low-k devices”, their wiring requires special industrial equipment and in particular “soft landing” wiring; the wiring of the thermal pads uses this same method.

These latest-generation chips have a very low tolerance to thermomechanical stresses, which is why the manufacturers of plastic packages for encapsulating them had to modify the properties of the resins (coefficient of expansion changing from 12 to 7 ppm/° C.); in other words, techniques using cut wires at a height of about 30 to 50 μm, or “studs”, which then have to be linked by soldering, for example, to a radiator made of copper; the link between the radiator and the chip is virtually rigid and the stresses imposed by the radiator are transferred to the chip; moreover, the linking of a multitude of studs through soldering is difficult to achieve because of the differential expansion stresses.

Finally, it is not prohibited to adopt the same approach on the rear face of the chip, with the drawback of having to pass through the thickness of silicon, provided that the latter is metalized like the pads of the active face.

1. A stack of at least one electronic chip device with improved thermal resistance comprising at least one electrical connection pad with an electrical interconnection link, at least one thermal pad arranged on a face of the chip, at least one heat exchange element, and at least one thermal link between a thermal pad and a heat exchange element, wherein a portion of a heat exchange element, said portion being situated facing an electrical connection pad, with an electrical interconnection link, of an electronic chip comprises an aperture preventing contact with said electrical interconnection link.

2. The stack as claimed in claim 1, wherein said heat exchange element comprises tabs arranged facing the corners of the corresponding chip.

3. The stack as claimed in claim 1, wherein the electronic chip device(s) comprise a portion of said heat exchange element, said portion being arranged facing a thermal pad, comprising an aperture.

4. The stack as claimed in claim 1, wherein the thermal link(s) of the electronic chip device(s) comprise at least one thermally conductive wire.

5. The stack as claimed in claim 1, wherein the face of a chip comprising at least one thermal pad is the active face of the chip.

6. The stack as claimed in claim 5, wherein a portion of a heat exchange element, said portion being situated facing electrical connection pads, with an electrical interconnection link of an electronic chip is raised in such a way as to avoid contact with said electrical interconnection link.

7. The stack as claimed in claim 1, wherein the front face of a chip comprising at least one thermal pad is the passive face of the chip.

8. The stack as claimed in claim 7, wherein the electronic chip device(s) comprise a substrate in which a portion situated facing electrical connection pads, with an electrical interconnection link, of the active face is provided with an aperture in such a way as to avoid contact with said electrical interconnection link.

9. A method for manufacturing an electronic chip device or a stack of electronic chip devices, comprising a mask-transfer step on the active face of the chip or chips, using a mask comprising at least one aperture intended for an electrical connection pad, and at least one aperture intended for a thermal pad.
